(19) United States
(12) Patent Application Publication
(10) Pub. No.: US 2026/0223570 A1
(43) Pub. Date: Jul. 30, 2026

(54) DISPLAY DEVICE

(71) Applicant: LG ELECTRONICS INC., Seoul (KR)

(72) Inventors: Minchul SHIN, Seoul (KR); Dongkyoon HAN, Seoul (KR); Seokwoo KWON, Seoul (KR)

(73) Assignee: LG ELECTRONICS INC., Seoul (KR)

(21) Appl. No.: 19/141,685

(22) PCT Filed: Dec. 21, 2022
(86) PCT No.: PCT/KR2022/020979

§ 371 Date: Jun. 20, 2025

(51) Int. Cl. H10K 59/80

(52) U.S. Cl. CPC H10K 59/871

(57) ABSTRACT

A display device is provided. The display device of the present disclosure may include: a display panel displaying an image and having light transparency; a back cover spaced rearward from the display panel and having light transparency; a side frame extending along an edge of the display panel between the display panel and the back cover; and a cover moving between the display panel and the back cover to open or close a rear surface of the display panel, wherein the side frame may include: a first portion covering a lateral side of the display panel; and a second portion which protrudes between the display panel and the back cover from the first portion and to which the display panel and the back cover are coupled.

### TECHNICAL FIELD

The present description relates to a display device. More particularly, the present disclosure relates to a display device including a transparent display panel.

### BACKGROUND ART

With the development of the information society, there have been growing demands for various types of display devices, and in order to meet these demands, various display devices, such as a liquid crystal display (LCD) device, a Plasma Display Panel (PDP), an electroluminescent display (ELD), a vacuum fluorescent display (VFD), an organic light emitting diode (OLED), etc., have been studied and used recently.

Among them, the LCD panel includes a TFT substrate and a color substrate which are positioned opposite each other with a liquid crystal layer interposed therebetween, and displays images by using light provided by a backlight unit. Further, the OLED panel may display images by using a self-emitting organic layer deposited on a substrate on which transparent electrodes are formed.

Recently, many studies are being conducted on a transparent display panel capable of not only displaying images to a user, but also allowing the user to see behind the display panel.

### DETAILED DESCRIPTION OF INVENTION

### Technical Problems

It is an objective of the present disclosure to solve the above and other problems.

Another object may be to provide a display device including a transparent display panel.

Another object may be to provide a cover for opening or closing the rear of a transparent display panel, and a mechanism thereof.

Another object may be to provide a side frame structure to which a transparent display panel and a transparent back cover are coupled.

Another object may be to provide a structure in which a side frame improves the rigidity of a display device.

Another object may be to provide a rail for guiding movement of a cover and a coupling structure of the rail and a side frame.

Another object may be to provide a structure and method for detecting and controlling the position of a cover.

### Technical Solution

In accordance with an aspect of the present disclosure for achieving the above and other objects, a display device may include: a display panel displaying an image and having light transparency; a back cover spaced rearward from the display panel and having light transparency; a side frame extending along an edge of the display panel between the display panel and the back cover; and a cover moving between the display panel and the back cover to open or close a rear surface of the display panel, wherein the side frame may include: a first portion covering a lateral side of the display panel; and a second portion which protrudes between the display panel and the back cover from the first portion and to which the display panel and the back cover are coupled.

### Effect of Invention

The display device according to the present disclosure has the following effects.

According to at least one of the embodiments of the present disclosure, a display device including a transparent display panel may be provided.

According to at least one of the embodiments of the present disclosure, there may be provided a cover for opening or closing the rear of a transparent display panel, and a mechanism thereof.

According to at least one of the embodiments of the present disclosure, there may be provided a side frame structure to which a transparent display panel and a transparent back cover are coupled.

According to at least one of the embodiments of the present disclosure, a structure in which a side frame improves the rigidity of a display device may be provided.

According to at least one of the embodiments of the present disclosure, a rail for guiding movement of a cover and a coupling structure of the rail and a side frame may be provided.

According to at least one of the embodiments of the present disclosure, a structure and method for detecting and controlling the position of a cover may be provided.

Further scope of applicability of the present disclosure will become apparent from the detailed description given hereinafter. However, it should be understood that the detailed description and specific examples, while indicating preferred embodiments of the present disclosure, are given by illustration only, since various changes and modifications within the spirit and scope of the present disclosure will become apparent to those skilled in the art from this detailed description.

### BRIEF DESCRIPTION OF THE DRAWING

FIGS. 1 to 29 are diagrams illustrating examples of a display device according to embodiments of the present disclosure.

MODE FOR CARRYING OUT THE INVENTION

Hereinafter, the present disclosure will be described in detail with reference to the accompanying drawings, in which the same reference numerals are used throughout the drawings to designate the same or similar components, and a redundant description thereof will be omitted.

The suffixes, such as “module” and “unit,” for elements used in the following description are given simply in view of the ease of the description, and do not have a distinguishing meaning or role.

In addition, it will be noted that a detailed description of known arts will be omitted if it is determined that the detailed description of the known arts can obscure the embodiments of the present disclosure. Further, the accompanying drawings are used to help easily understand various technical features and it should be understood that the embodiments presented herein are not limited by the accompanying drawings. As such, the present disclosure should be construed to extend to any alterations, equivalents and substitutes in addition to those which are particularly set out in the accompanying drawings.

It will be understood that, although the terms first, second, etc., may be used herein to describe various elements, these elements should not be limited by these terms. These terms are only used to distinguish one element from another.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

A singular representation may include a plural representation unless context clearly indicates otherwise.

It should be understood that the terms “comprise,” “include,” “have,” etc. when used in this specification, specify the presence of stated features, integers, steps, operations, elements, components, or combinations thereof but do not preclude the presence or addition of one or more other features, integers, steps, operations, elements, components, or combinations thereof.

References to directions, such as up (U), down (D), left (Le), right (Ri), front (F), and rear (R), shown in the drawings are provided merely for convenience of explanation and are not intended to limit the scope of the present disclosure.

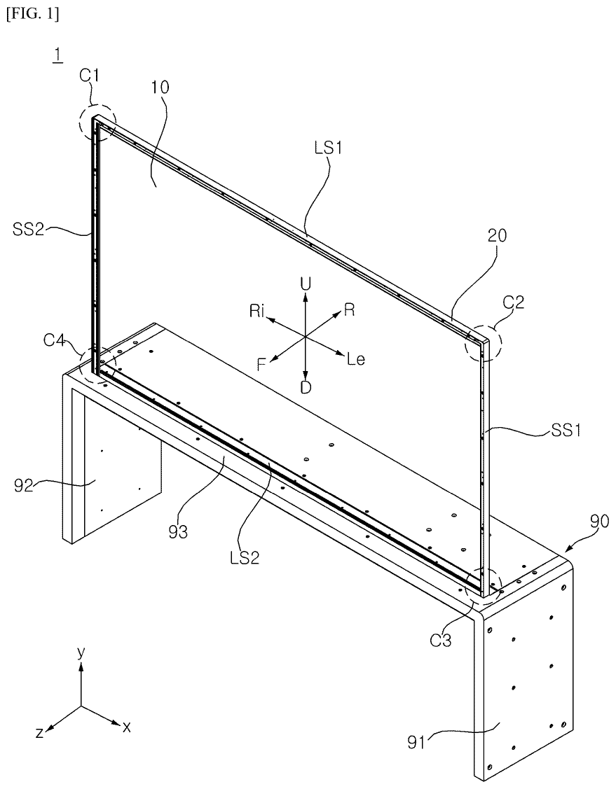

Referring to FIG. 1, a display device 1 may include a display 10, a side frame 20, and a housing 90. The display 10 may display an image. The side frame 20 may extend along the perimeter of the display 10. The housing 90 may be located below the display 10 and the side frame 20. Alternatively, the housing 90 may be located on the upper side, the left side, or the right side of the display 10 and the side frame 20. For example, the housing 90 may have a desk shape as a whole, and may include a top plate coupled to one side of the display 10 and legs 91 and 92 placed on the ground.

The display 10 may include a first long side LS1, a second long side LS2 opposite to the first long side LS1, a first short side SS1 adjacent to the first and the second long sides LS1 and LS2, and a second short side SS2 opposite to the first short side SS1. Meanwhile, for convenience of explanation, it is illustrated and described that the first and second long sides LS1 and LS2 are longer than the first and second short sides SS1 and SS2, but it is also possible that the lengths of the first and second long sides LS1 and LS2 may be approximately equal to the lengths of the first and second short sides SS1 and SS2.

The long sides LS1 and LS2 and the short sides SS1 and SS2 of the display 10 may be formed on the side frame 20.

A direction parallel to the long sides LS1 and LS2 of the display 10 may be referred to as a left-right direction. A direction parallel to the short sides SS1 and SS2 of the display 10 may be referred to as an up-down direction. A direction perpendicular to the long sides LS1 and LS2 and the short sides SS1 and SS2 of the display 10 may be referred to as a front-rear direction.

A side on which the display 10 displays an image may be referred to as a front side F, z, and a side opposite thereto may be referred to as a rear side R. The first short side SS1 may be referred to as a left side Le, x, and the second short side SS2 may be referred to as a right side Ri. The first long side LS1 may be referred to as an upper side U, y, and the second long side LS2 may be referred to as a lower side D.

The first long side LS1, the second long side LS2, the first short side SS1, and the second short side SS2 may be referred to as edges of the display 10. Further, positions where the first long side LS1, the second long side LS2, the first short side SS1, and the second short side SS2 meet each other may be referred to as corners. A position where the first long side LS1 and the second short side SS2 meet may be referred to as a first corner C1. A position where the first long side LS1 and the first short side SS1 meet may be referred to as a second corner C2. A position where the second long side LS2 and the first short side SS1 meet may be referred to as a third corner C3. A position where the second long side LS2 and the second short side SS2 meet may be referred to as a fourth corner C4.

Hereinafter, a display panel using an Organic Light Emitting Diode (OLED) will be described as an example, but the display panel applicable to the present disclosure is not limited thereto.

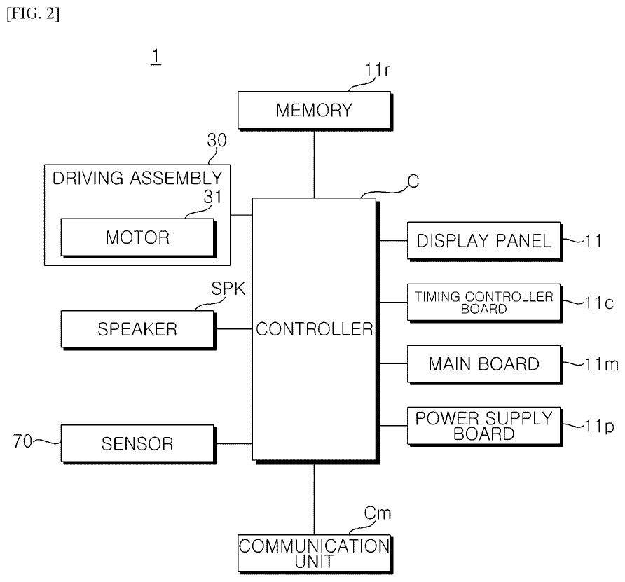

Referring to FIG. 2, a controller C of the display device 1 may control the operation of the display device 1. The controller C may be electrically connected to components of the display device 1.

A display panel 11, a main board 11m, a power supply board 11p, and a timing controller board 11c may be installed in an inner space of the housing 90 and may be electrically connected to the controller C. The main board 11m may control the display device 1. The controller C may be implemented as the main board 11m or may be a superordinate control unit that controls the main board 11m and the like. The power supply board 11p may provide power to each component of the display device 1. The timing controller board 11c may provide an image signal to the display panel 11.

A motor 31 of a driving assembly 30 may be electrically connected to the controller C. The controller C may control the operation of the motor 31. The controller C may control the rotation amount (rotation angle), rotation direction, and rotation speed of the motor 31. For example, the motor 31 may be a step motor.

A speaker SPK may be installed in the inner space of the housing 90. The speaker SPK may be electrically connected to the controller C. A speaker hole (not shown) may be formed in the housing 90, and the speaker SPK may provide sound through the speaker hole.

A communication unit Cm may transmit information of the display device 1 to an external device or transmit various types of information or signals from an external device to the display device 1. The communication unit Cm may perform communication with a remote control device, a portable terminal, a wired/wireless router, or other communication infrastructure (e.g., a server), etc. For example, the communication unit Cm may perform wireless communication with an external device by using a communication technology such as IEEE 802.11 WLAN, IEEE 802.15 WPAN, UWB, Wi-Fi, Zigbee, Z-wave, Blue-Tooth, and the like.

A memory 11r may be electrically connected to the controller C. The memory 11r may store basic data (e.g., basic specification information for each configuration of the display device, such as display resolution, brightness, sound output value, etc.) for the display device 1, data and programs for controlling the operation of the display device 1, data input from the outside, or data processed by the controller C, or the like. For example, the memory 11r may store information related to the operation of the motor 31. For example, the memory 11r may include ROM, RAM, EPROM, a flash drive, a hard drive, or the like. For example, the memory 11r may be classified as a sub-component of the controller C.

Meanwhile, a sensor 70 which will be described later may be electrically connected to the controller C.

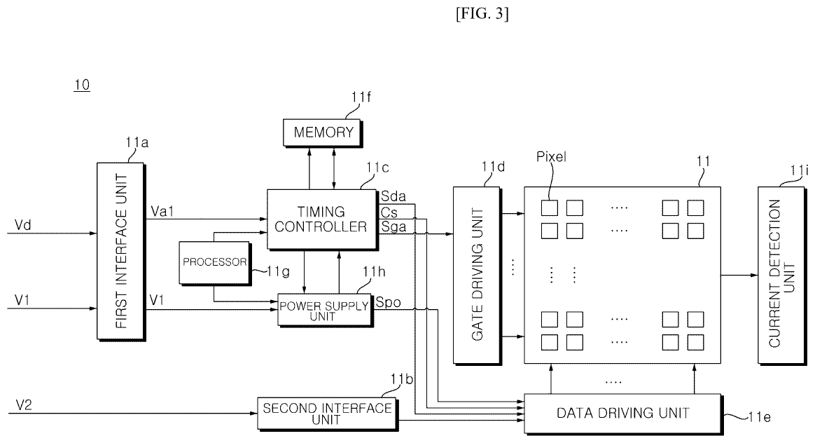

Referring to FIG. 3, the display 10 may include a display panel 11, a first interface unit 11a, a second interface unit 11b, a timing controller 11c, a gate driving unit 11d, a data driving unit 11e, a memory 11f, a processor 11g, a power supply unit 11h, and a current detection unit 11i. The display panel 11 may be an Organic Light Emitting Diode (OLED) panel.

The first interface unit 11a may receive first direct current (DC) power VI from a power supply unit external to the display 10, and the first DC power V1 may be supplied for the operation of the power supply unit 11h and the timing controller 11c.

The second interface unit 11b may receive second DC power V2 from a power supply unit external to the display 10, and the second DC power V2 may be supplied to the data driving unit 11e.

The timing controller 11c may output a data driving signal Sda and a gate driving signal Sga based on an image signal Vd input to the first interface unit 11a. For example, the first interface unit 11a may convert the image signal Vd and output a converted image signal Val, and the timing controller 11c may output a data driving signal Sda and a gate driving signal Sga based on the converted image signal Val. The data driving signal Sda may be a driving signal for subpixels of the display panel 11. In addition, the timing controller 11c may further output a control signal Cs to the data driving unit 11e.

The gate driving unit 11d and the data driving unit 11e may provide a scanning signal and an image signal to the display panel 11 through a gate line GL and a data line DL according to the gate driving signal Sga and the data driving signal Sda of the timing controller 11c. Accordingly, the display panel 11 may display an image.

The power supply unit 11h may provide various types of power to the gate driving unit 11d, the data driving unit 11e, the timing controller 11c, and the like.

The current detection unit 11i may detect the current flowing in the subpixel of the display panel 11. The detected current may be input to the processor 11g for calculation of cumulative current. The calculated cumulative current may be stored in the memory 11f.

The processor 11g may perform various controls within the display 10. For example, the processor 11g may control the gate driving unit 11d, the data driving unit 11e, the timing controller 11c, and the like.

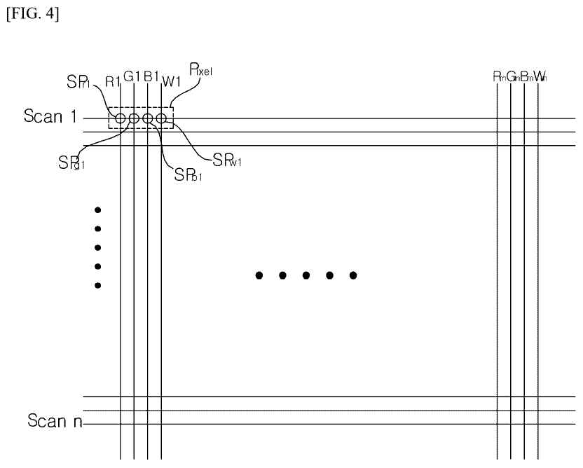

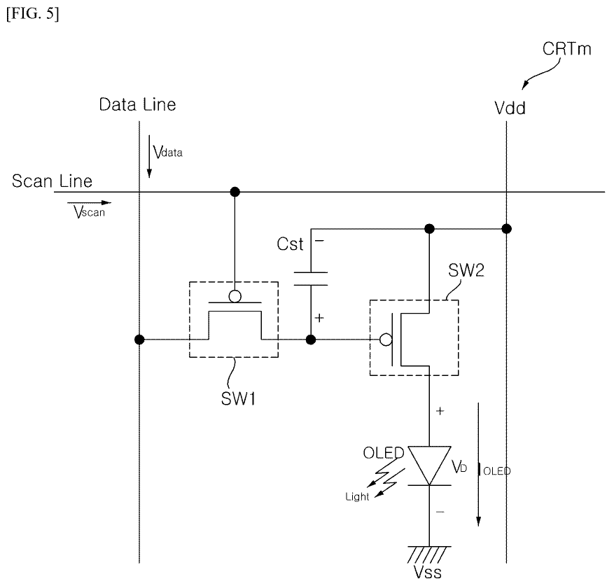

Referring to FIGS. 4 and 5, the display panel 11 may include a plurality of scan lines Scan 1 to Scan n and a plurality of data lines R1, G1, B1, W1 to Rm, Gm, Bm, Wm. The plurality of data lines R1, G1, B1, W1 to Rm, Gm, Bm, Wm may intersect with the plurality of scan lines Scan 1 to Scan n. A subpixel may be defined in an intersection area of the scan line and the data line. A pixel may be a hold type element that continuously emits light in an organic light-emitting layer (OLED) during a unit frame image after a scan signal is applied. For example, a pixel may include RGBW subpixels. In another example, a pixel may include RGB subpixels.

The circuit CRTm of the subpixel may be an active type, and may include a scan switching element SW1, a storage capacitor Cst, a driving switching element SW2, and an organic light-emitting layer OLED.

The scan switching element SW1 may be turned on according to a scan signal Vscan input from the scan line. When the scan switching element SW1 is turned on, the scan switching element SW1 may transmit a data signal Vdata input from the data line to one end of the storage capacitor Cst or the gate terminal of the driving switching element SW2.

The storage capacitor Cst may be provided between the gate terminal and the source terminal of the driving switching element SW2, and may store a difference between the level of the data signal transmitted to one end of the storage capacitor Cst and the level of the DC power VDD transmitted to the other end of the storage capacitor Cst.

For example, if the data signal has a different level according to a Pulse Amplitude Modulation (PAM) method, the power level stored in the storage capacitor Cst may vary according to the level difference of the data signal Vdata. In another example, if the data signal has a different pulse width according to a Pulse Width Modulation (PWM) method, the power level stored in the storage capacitor Cst may vary according to a difference in pulse width of the data signal Vdata.

The driving switching element SW2 may be turned on according to the power level stored in the storage capacitor Cst. When the driving switching element SW2 is turned on, a driving current IOLED proportional to the stored power level may flow to the organic light-emitting layer OLED. Accordingly, the organic light-emitting layer OLED may perform a light-emitting operation.

The organic light-emitting layer OLED may include an RGBW light-emitting layer EML corresponding to a subpixel, may include at least one of a hole injection layer HIL, a hole transport layer HTL, an electron transport layer ETL, or an electron injection layer EIL, and may also include a hole blocking layer HBL, or the like.

Meanwhile, FIG. 5 illustrates a p-type MOSFET as a scan switching element SW1 and a driving switching element SW2, but a switching element such as an n-type MOSFET, JFET, IGBT, or SIC may also be used.

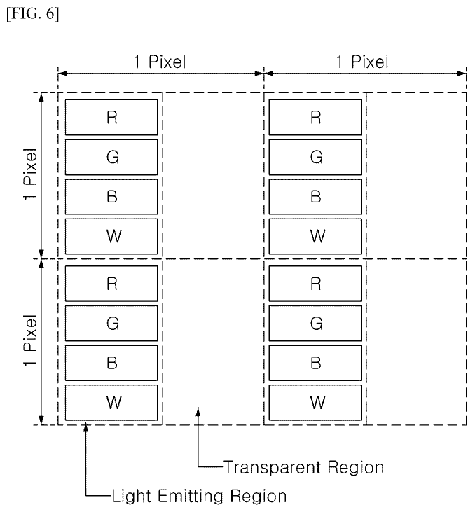

Referring to FIG. 6, a pixel may include a light emitting region and a transparent region. Red, Green, Blue, and White (RGBW) subpixels may be arranged vertically in the light emitting region, and the transparent region with no subpixels may be arranged next to the light emitting region.

Accordingly, the display panel 11 having a plurality of pixels may not only display an image but also transmit light. The display panel 11 may be referred to as a transparent display panel or a transparent OLED panel.

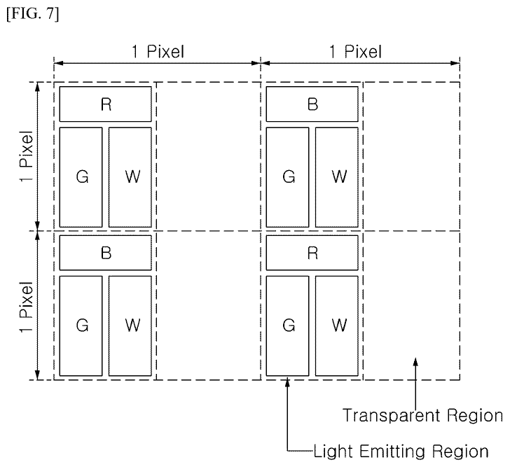

Referring to FIG. 7, a pixel may include a light emitting region and a transparent region. Red, Green and White (RGW) subpixels or Blue, Green and White (BGW) subpixels may be arranged next to each other in the light emitting region, and the transparent region with no subpixels may be arranged next to the light emitting region.

Accordingly, the display panel 11 having a plurality of pixels may not only display an image but also transmit light. The display panel 11 may be referred to as a transparent display panel or a transparent OLED panel.

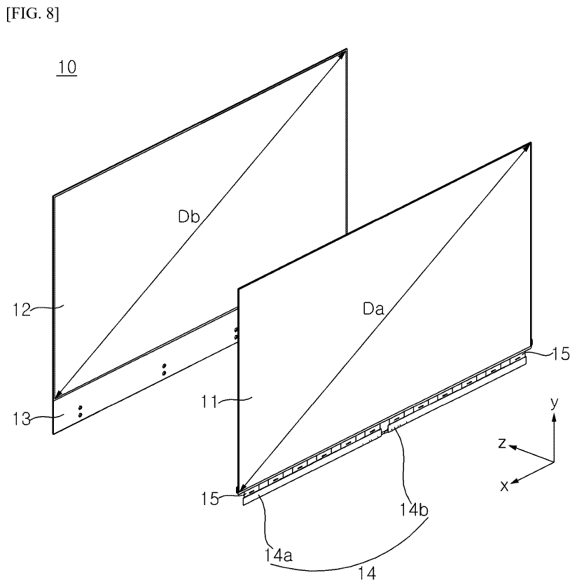

Referring to FIG. 8, the display panel 11 may output an image by dividing an image into a plurality of pixels and adjusting the color, brightness, and saturation for each pixel. The display panel 11 may be divided into an active area where an image is displayed and a de-active area where an image is not displayed. The display panel 11 may generate light corresponding to red (R), green (G), or blue (B) color in response to a control signal.

A source PCB 14 may be adjacent to the lower side of the display panel 11. The source PCB 14 may extend along the lower side of the display panel 11. The source PCB 14 may be electrically connected to the display panel 11 through a Chip On Film (COF) 15. The source PCB 14 may be electrically connected to the timing controller board 11c (see FIG. 2) through a cable (not shown) such as a Flexible Flat Cable (FFC).

The transparent panel 13 may be located at the front of the display panel 11. The transparent panel 13 may be made of transparent glass. An adhesive film 12 may be located between the display panel 11 and the transparent panel 13, and may be coupled to the display 11 panel 11 and the transparent panel 13. The adhesive film 12 may be an Optically Clear Adhesive (OCA) film.

In addition, the adhesive film 12 may cover at least a portion of the rear surface of the transparent panel 13. For example, one side of the adhesive film 12 may be located closer to the center of the display panel 11 than one side of the transparent panel 13 that corresponds thereto. For example, the upper side, left side, and right side of the adhesive film 12 may be respectively adjacent to the upper side, left side, and right side of the transparent panel 13, and the lower side of the adhesive film 12 may be spaced above the lower side of the transparent panel 13.

In addition, the size of the adhesive film 12 may correspond to the size of the display panel 11. For example, a diagonal length Db of the adhesive film 12 may be substantially equal to a diagonal length Da of the display panel 11. In another example, the diagonal length Db of the adhesive film 12 may be greater than the diagonal length Da of the display panel 11. In this case, a portion of the adhesive film 12 may be located along the perimeter of the display panel 11 on the outside of the display panel 11.

Meanwhile, the display panel 11, the adhesive film 12, and the transparent panel 13 may be referred to as the display 10.

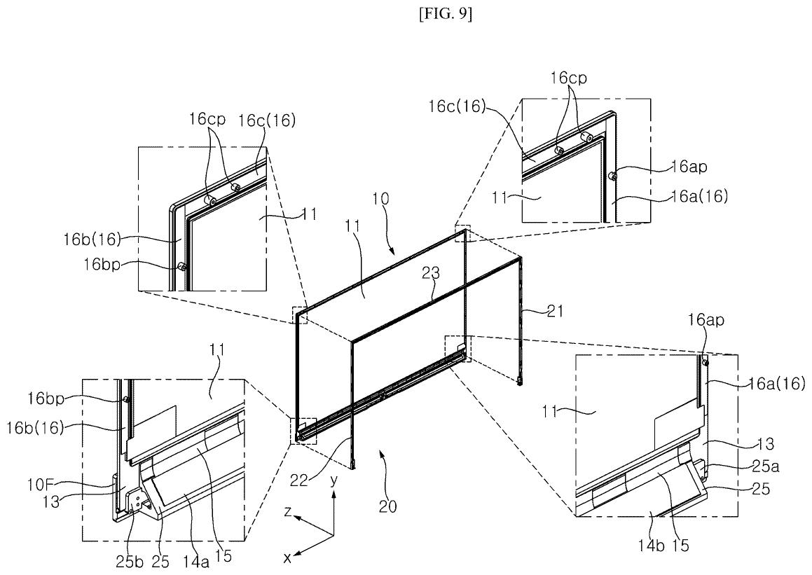

Referring to FIG. 9, a fixing member 16 may be adjacent to the perimeter of the display panel 11 and may extend along the perimeter of the display panel 11. For example, the fixing member 16 may be coupled to the rear surface of the adhesive film 12 (see FIG. 8) on the outside of the display panel 11.

A first fixing member 16a may extend along the right side of the display panel 11 and may be attached or fixed to the rear surface of the transparent panel 13. A first fixing portion 16ap may protrude rearward from the first fixing member 16a.

A second fixing member 16b may extend along the left side of the display panel 11 and may be attached or fixed to the rear surface of the transparent panel 13. A second fixing portion 16bp may protrude rearward from the second fixing member 16b.

A third fixing member 16c may extend along the upper side of the display panel 11 and may be attached or fixed to the rear surface of the transparent panel 13. A third fixing portion 16cp may protrude rearward from the third fixing member 16c.

A bracket 25 may extend along the lower side of the transparent panel 13 and may be attached or fixed to the rear surface of the transparent panel 13. The bracket 25 may include a metal material such as aluminum (Al). The bracket 25 may have a right-angled triangular cross-section. The COF 15 may be located between the lower side of the display panel 11 and the upper end of the bracket 25. A source PCB 14a, 14b may be located on the oblique side of the bracket 25. A first fixing portion 25a may protrude rightward from the right end of the bracket 25, may contact the rear surface of the transparent panel 13, and may have a plurality of holes. A second fixing portion 25b may protrude leftward from the left end of the bracket 25, may contact the rear surface of the transparent panel 13, and may have a plurality of holes.

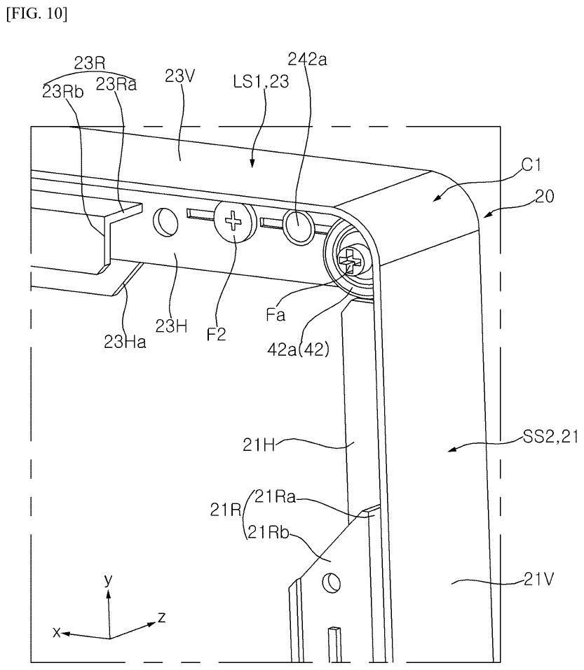

Referring to FIGS. 9 and 10, the side frame 20 may be located at the rear of the fixing member 16 and may extend along the fixing member 16. The side frame 20 may include a first side frame 21, a second side frame 22, and a third side frame 23.

The first side frame 21 may extend along the first fixing member 16a. The first side frame 21 may include a first horizontal portion 21H, a first vertical portion 21V, and a first rib 21R.

The first horizontal portion 21H may be positioned opposite and parallel to the first fixing member 16a, and a fastening member, such as a screw, may pass through the first horizontal portion 21H to be fastened to the first fixing portion 16ap of the first fixing member 16a. The first fixing portion 16ap may be referred to as a first pem-nut 16ap. Alternatively, the first horizontal portion 21H may be directly attached or fixed to the rear surface of the front panel 13 without the first fixing member 16a.

The first vertical portion 21V may intersect the first horizontal portion 21H to define the second short side SS2 and may cover the right side of the first fixing member 16a.

The first rib 21R may be opposite the first fixing member 16a with respect to the first horizontal portion 21H. A first vertical rib 21Ra may protrude rearward from the rear surface of the first horizontal portion 21H and may extend along the first horizontal portion 21H. The first horizontal rib 21Rb may be bent from the rear end of the first vertical rib 21Ra in a direction opposite to the first vertical portion 21V and may face the first horizontal portion 21H.

The first horizontal portion 21H, the first vertical portion 21V, and the first rib 21R which are described above may be formed as one body. For example, the first side frame 21 may include a metal material such as aluminum (Al). Accordingly, the first side frame 21 may improve torsional rigidity and/or bending rigidity. In addition, the first side frame 21 may cover the right side of the display panel 11.

The second side frame 22 may extend along the second fixing member 16b. The second side frame 22 may be laterally symmetrical to the first side frame 21. That is, a second horizontal portion (fastened to the second fixing portion 16bp), a second vertical portion (covering the left side of the second fixing member 16b), and a second rib of the second side frame 22 may be formed as one body. For example, the second side frame 22 may include a metal material such as aluminum (Al). Accordingly, the second side frame 22 may improve torsional rigidity and/or bending rigidity of the display 10. In addition, the second side frame 22 may cover the left side of the display panel 11.

The third side frame 23 may extend along the third fixing member 16c. The third side frame 23 may include a third horizontal portion 23H, a third vertical portion 23V, and a third rib 23R.

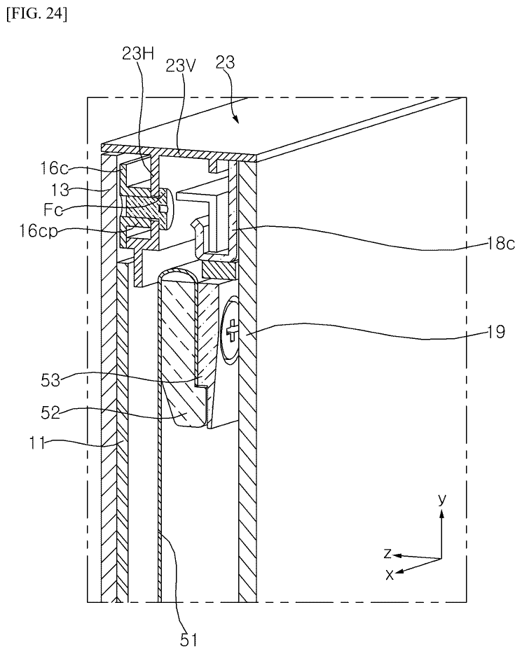

The third horizontal portion 23H may be positioned opposite and parallel to the third fixing member 16c, and a fastening member Fc (see FIG. 24), such as a screw, may pass through the third horizontal portion 23H to be fastened to the third fixing portion 16cp of the third fixing member 16c. The third fixing portion 16cp may be referred to as a third pem-nut 16cp. Alternatively, the third horizontal portion 23H may be directly attached or fixed to the rear surface of the front panel 13 without the third fixing member 16c.

The third vertical portion 23V may intersect the third horizontal portion 23H to define the first long side LS1, and may cover the upper side of the third fixing member 16c.

The third rib 23R may be opposite the third fixing member 16c with respect to the third horizontal portion 23H. A third vertical rib 23Ra may protrude rearward from the rear surface of the third horizontal portion 23H and may extend along the third horizontal portion 23H. The third horizontal rib 23Rb may be bent from the rear end of the third vertical rib 23Ra in a direction opposite to the third vertical portion 23V and may face the third horizontal portion 23H.

The third horizontal portion 23H, the third vertical portion 23V, and the third rib 23R which are described above may be formed as one body. For example, the third side frame 23 may include a metal material such as aluminum (Al). Accordingly, the third side frame 23 may improve torsional rigidity and/or bending rigidity of the display 10. In addition, the third side frame 23 may cover the upper side of the display panel 11.

For example, the first side frame 21, the second side frame 22, and the third side frame 23 may be formed as one body. For example, the side frames 21, 22, and 23 may be manufactured by extrusion molding. The first side frame 21 may be bent downward at the right end of the third side frame 23. The second side frame 22 may be bent downward at the left end of the third side frame 23. The first corner C1 may be formed at a position where the first side frame 21 and the third side frame 23 meet, and the second corner C2 (see FIG. 1) may be formed at a position where the second side frame 22 and the third side frame 23 meet. Accordingly, the side frame 20 may improve the torsional rigidity and/or the bending rigidity of the display 10. In addition, the side frame 20 may cover the lateral sides of the display panel 11.

Meanwhile, the lower end of the first side frame 21 may be coupled or fixed to the first fixing portion 25a, and the lower end of the second side frame 22 may be coupled or fixed to the second fixing portion 25b of the bracket 25. Alternatively, the bracket 25 may also be formed as one body with the side frame 20.

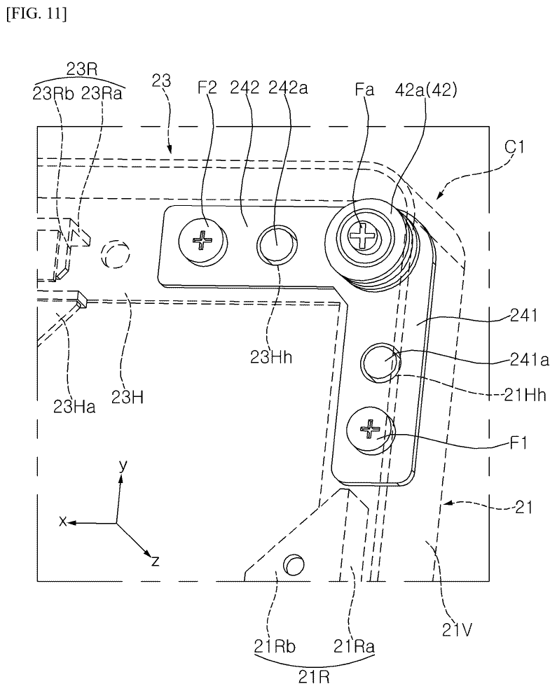

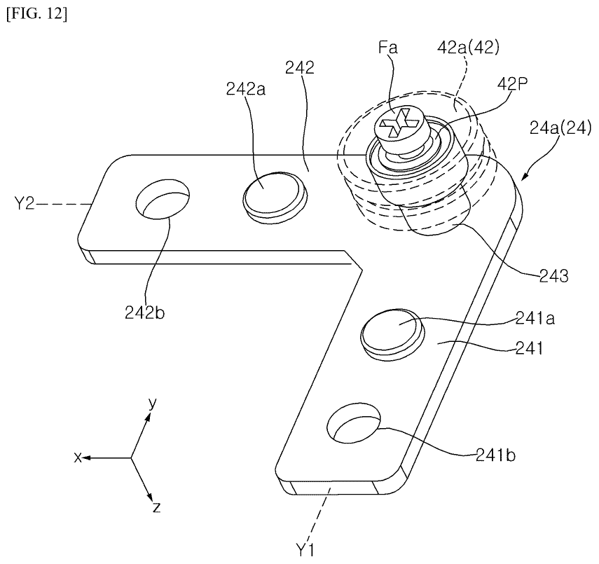

Referring to FIGS. 11 and 12, a corner brace 24 may be located at both ends of the third side frame 23. A first corner brace 24a may be adjacent to the first corner C1 and may be connected to the third side frame 23 and the first side frame 21. A second corner brace 24b may be adjacent to the second corner C2 (see FIG. 1) and may be connected to the third side frame 23 and the second side frame 22 (see FIG. 9). The second corner brace 24b may be laterally symmetrical to the corner bracket 24a.

Specifically, the corner brace 24 may be generally L-shaped. The corner brace 24 may be referred to as an L-shaped bracket 24, an L-shaped plate 24, or a fixer 24. The first part 241 may extend along a first axis Y1 that is parallel to the first side frame 21 or the second side frame 22, and may be referred to as a vertical part 241. The second part 242 may extend along a second axis Y2 that is parallel to the third side frame 23, and may be referred to as a horizontal part 242. A first protrusion 241a may protrude rearward from the rear surface of the first part 241, and a second protrusion 242a may protrude rearward from the rear surface of the second part 242. A first hole 241b may be formed in the first part 241, and a second hole 242b may be formed in the second part 242.

In this case, the first part 241 of the first corner brace 24a may be located on the front surface of the first horizontal portion 21H of the first side frame 21, and the second part 242 of the first corner brace 24a may be located on the front surface of the third horizontal portion 23H of the third side frame 23. The first protrusion 241a may pass through a hole 21Hh of the fist horizontal portion 21H, and a first fastening member F1, such as a screw, may pass through the first horizontal portion 21H to be fastened to the first hole 241b. The second protrusion 242a may pass through a hole 23Hh of the third horizontal portion 23H, and a second fastening member F2, such as a screw, may pass through the third horizontal portion 23H to be fastened to the second hole 242b. Accordingly, the first corner brace 24a may be coupled to the first side frame 21 and the third side frame 23, and may minimize splaying or separation or warping of the first side frame 21 and the third side frame 23. Likewise, the second corner brace 24b may be coupled to the second side frame 22 and the third side frame 23, and may minimize splaying or separation or warping of the second side frame 22 and the third side frame 23.

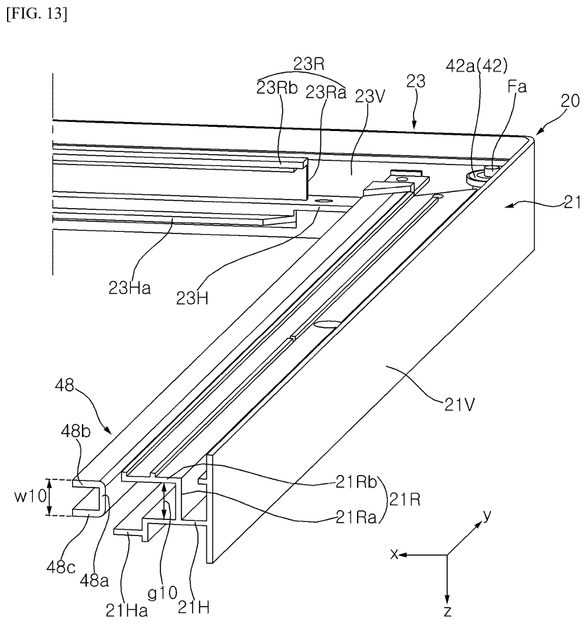

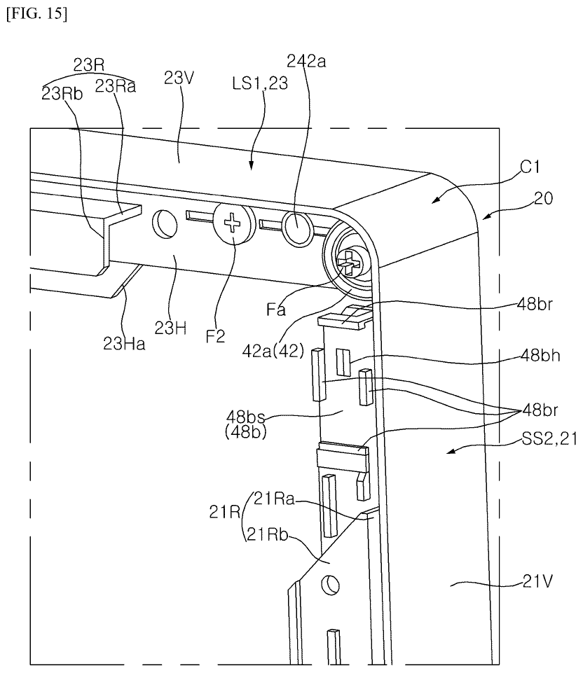

Referring to FIGS. 13 to 15, a first rail 48 may extend along the first side frame 21. The first rail 48 may have a C-shaped cross-section. The first rail 48 may include a side part 48a, a rear part 48b, and a front part 48c. The side part 48a may face the inside of the first vertical rib 21Ra. The rear part 48b may be bent from the rear end of the side part 48a and may face the inside of the first horizontal rib 21Rb. The front part 48c may be bent from the front end of the side part 48a and may face the inside of the first horizontal portion 21H. A distance w10 between the front and rear surfaces of the first rail 48 may be equal or similar to a distance g10 between the first horizontal rib 21Rb and the first horizontal portion 21H.

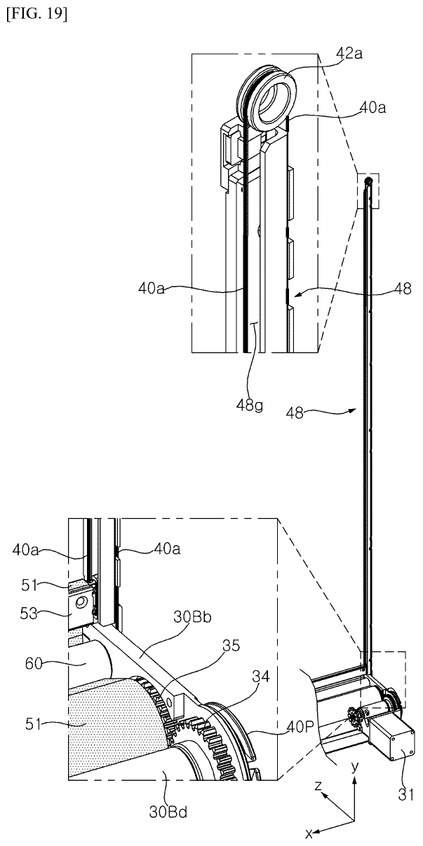

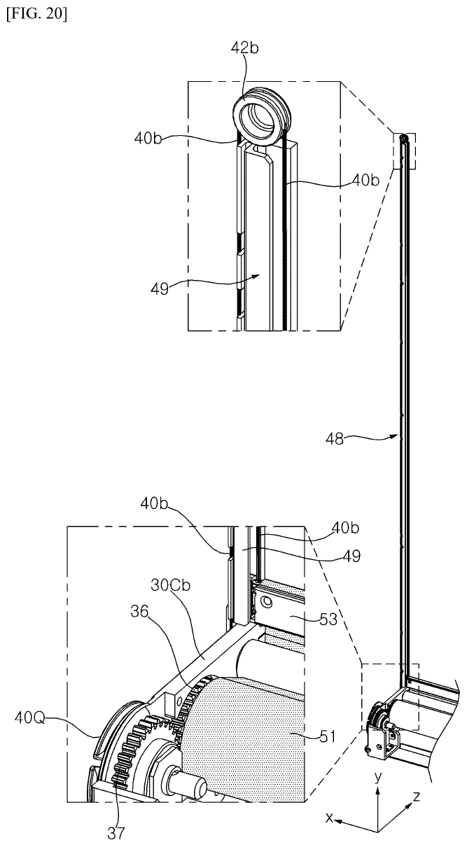

In this case, the first rail 48 may be inserted between the first horizontal rib 21Rb and the first horizontal portion 21H. The first rail 48 may be elastic. A first catching protrusion 48d may be formed on the surface of the rear part 48b or the surface of the front part 48c, and may be removably caught by a first catching hole 21Rd (or a first catching recess) formed in the first horizontal rib 21Rb or the first horizontal portion 21H. The first catching protrusion 48d may be referred to as a first tension latch 48d. The first catching protrusion 48d may be elongated along the first rail 48 or may include a plurality of first catching protrusions 48d which are spaced apart from each other in a longitudinal direction of the first rail 48. Accordingly, the first rail 48 may be inserted between the first horizontal rib 21Rb and the first horizontal portion 21H to be coupled to the first side frame 21. A second rail 49 (see FIGS. 19 and 20) which will be described later may be laterally symmetrical to the first rail 48. That is, the second rail 49 may be coupled to the second side frame 22.

Meanwhile, the top portion of the first rail 48 may not be covered by the first horizontal rib 21Rb, and may be exposed to the rear.

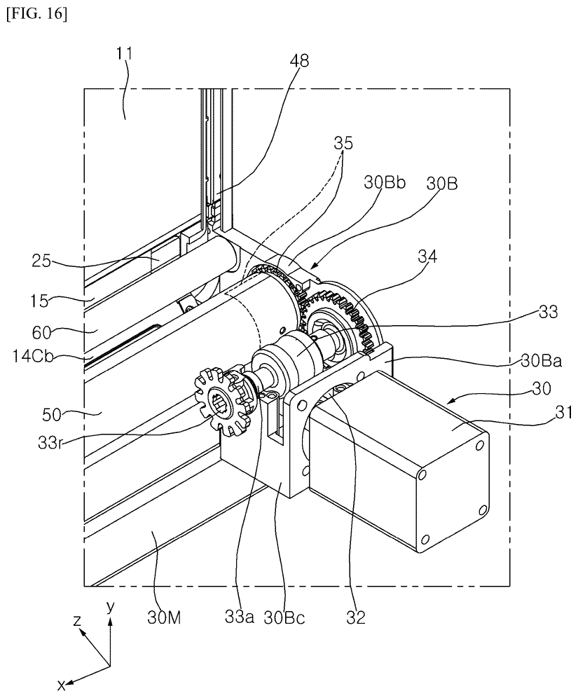

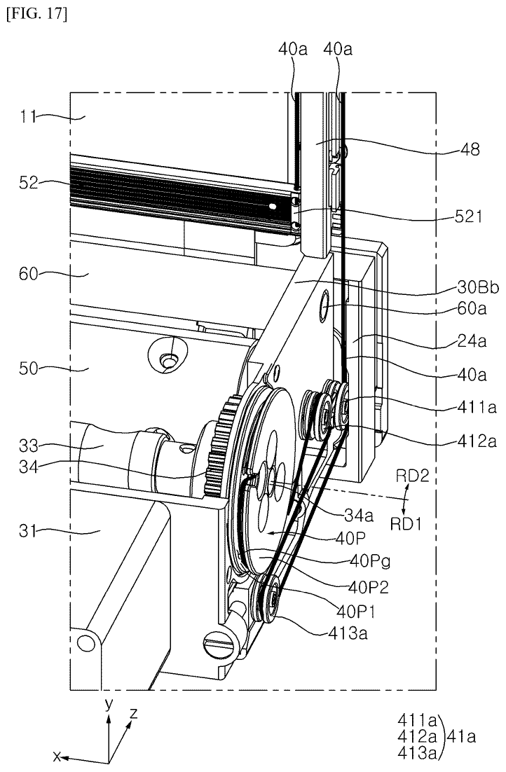

Referring to FIGS. 16 and 17, the driving assembly 30 may include a base 30M, a first mount 30B, a motor 31, a worm 32, a worm wheel 33, a first gear 34, a second gear 35, and a first lower pulley 41a. The driving assembly 30 may be adjacent to the lower side of the display panel 11. Alternatively, the driving assembly 30 may be adjacent to the upper side, the left side, or the right side of the display panel 11.

The base 30M may be located at the rear of the bracket 25. The base 30M may be a thin plate that is elongated in the left-right direction, and may be fixed to the inside of the housing 90 (see FIG. 1).

The first mount 30B may be located on the base 30M and adjacent to the right end of the base 30M. The first mount 30B may include a first rear part 30Ba, a first side part 30Bb, and a first support part 30Bc. The first rear part 3Ba may have a square plate shape that is parallel to the XY plane. The first side part 30Bb may protrude forward from the right side of the first rear part 30Ba. The first side part 30Bb may be referred to as a first side wall 30Bb. The first support part 30Bc may protrude forward from the left side of the first rear part 30Ba and may be located on the base 30M. The first rear part 30Ba, the first side part 30Bb, and the first support part 30Bc may be formed as one body.

The motor 31 may be located at the rear of the first rear part 30Ba. The motor 31 may provide torque. The motor 31 may be an electric motor with adjustable rotation direction, rotation angle, and rotation speed. A rotating shaft of the motor 31 may extend in the front-rear direction and pass through the first rear part 30Ba.

The worm 32 may be located between the first side part 30Bb and the first support part 30Bc. One end of the worm 32 may be fixed to the rotating shaft of the motor 31, and may rotate together with the rotating shaft. Screw-shaped gear teeth may be formed on an outer circumferential surface of the worm 32, and the worm 32 may be referred to as a worm shaft 32.

The worm wheel 33 may be located between the first side part 30Bb and the first support part 30Bc, and may be located above the worm 32. The worm wheel 33 may mesh with the gear teeth of the worm 32. A rotation axis of the worm wheel 33 may be orthogonal to a rotation axis of the worm 32. Here, the rotation axis of the worm 32 may extend in the front-rear direction, and the rotation axis of the worm wheel 33 may extend in the left-right direction. The worm wheel 33 may be a helical gear.

The first gear 34 may be fixed to one end of the worm wheel 33. A rotation axis of the first gear 34 may be coaxial with the rotation axis of the worm wheel 33. The first gear 34 may be a spur gear. Further, the first gear 34 may be in contact with or adjacent to the inside of the first side part 30Bb. A shaft 34a of the first gear 34 may pass through the first side part 30Bb and provide a rotation axis of the first gear 34.

The second gear 35 may be located in front of the first gear 34 and may mesh with the first gear 34. A rotation axis of the second gear 35 may be parallel to the rotation axis of the first gear 34. Accordingly, the second gear 35 may rotate together with the first gear 34. The second gear 35 may be a spur gear. Further, the second gear 35 may be in contact with or adjacent to the inside of the first side part 30Bb. A shaft of the second gear 35 may pass through the first side part 30Bb and provide a rotation axis of the second gear 35.

A first lower pulley 41a may be rotatably coupled or fixed to the outer lateral surface of the first side part 30Bb. A rotation axis of the first lower pulley 41a may be parallel to the rotation axis of the first sand second gears 34 and 35. A first guide pulley 411a may be adjacent to the front end of the first side part 30Bb. A first tension pulley 412a, 413a may be located behind the first guide pulley 411a.

A roller 50 may be elongated in the left-right direction which is a direction parallel to the rotation axis of the second gear 35. The roller 50 may be in the shape of a hollow cylinder. The second gear 35 may be adjacent to the right end of the roller 50. A portion of the second gear 35 (see the dotted line in FIG. 16) may be located inside the roller 50 and fixed to the roller 50. Accordingly, the roller 50 may rotate together with the second gear 35.

A sub-roller 60 may be elongated in the left-right direction which is a longitudinal direction of the roller 50. The sub-roller 60 may have a cylindrical shape. The sub-roller 60 may be disposed between the roller 50 and the display panel 11, and a first shaft 60a of the sub-roller 60 may pass through the first side part 30Bb. The first shaft 60a may provide a rotation axis of the sub-roller 60. Alternatively, the sub-roller 60 may also be fixed to the first side part 30Bb. The sub-roller 60 may be referred to as an auxiliary roller 60.

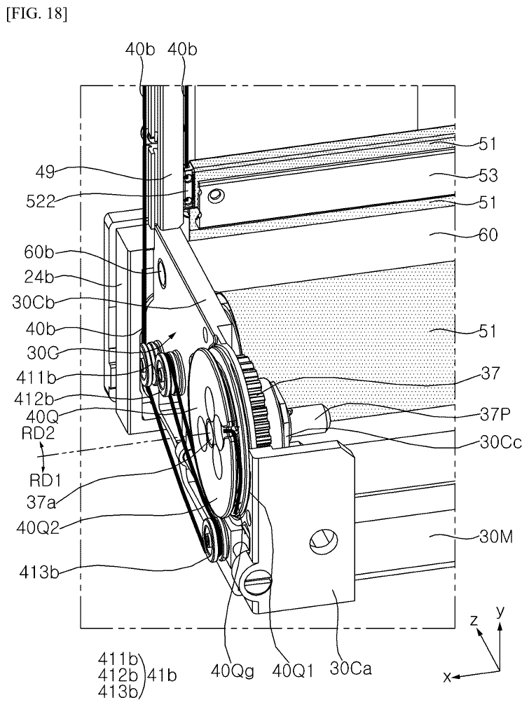

Referring to FIG. 18, a second mount 30C may be located on the base 30M and may be adjacent to the left end of the base 30M. The second mount 30C may include a second rear part 30Ca and a second side part 30Cb. The second rear part 30Ca may have a square plate shape that is parallel to the XY plane. The second side part 30Cb may protrude forward from the left side of the second rear part 30Ca. The second side part 30Cb may be referred to as a second side wall 30Cb. The second rear part 30Ca and the second side part 30Cb may be formed as one body. The second support part 30Cc may be coupled to the second mount 30C and spaced apart from the second side part 30Cb in the right direction.

A third gear 36 (see FIG. 20) may be adjacent to the left end of the roller 50. A portion of the third gear 36 may be located inside the roller 50 and fixed to the roller 50. A rotation axis of the third gear 36 may be parallel to the left-right direction which is the longitudinal direction of the roller 50. Accordingly, the third gear 35 may rotate together with the roller 50. The third gear 36 may be a spur gear. Further, the third gear 36 may be in contact with or adjacent to the inside of the second side part 30Cb. A shaft of the third gear 36 may pass through the second side part 30Cb and provide a rotation axis of the third gear 36.

The fourth gear 37 may be located behind the third gear 36 and may mesh with the third gear 37. A rotation axis of the fourth gear 37 may be parallel to the rotation axis of the third gear 36. Accordingly, the fourth gear 37 may rotate together with the third gear 36. The fourth gear 37 may be a spur gear. Further, the fourth gear 37 may be disposed between the second side part 30Cb and the second support part 30Cc and may be in contact with or adjacent to the inside of the second side part 30Cc. A shaft 37a of the fourth gear 37 may pass through the second side part 30Cb and provide a rotation axis of the fourth gear 37. A pin 37P of the fourth gear 37 may be opposite the shaft 37a and rotatably coupled to the second support par 30Cc.

A second lower pulley 41b may be rotatably coupled or fixed to the outer lateral surface of the second side part 30Cb. A rotation axis of the second lower pulley 41b may be parallel to the rotation axis of the third and fourth gears 36 and 37. A second guide pulley 411b may be adjacent to the front end of the second side part 30Cb. A second tension pulley 412b, 413b may be located behind the second guide pulley 411b.

A second shaft 60b of the sub-roller 60 may pass through the second side part 30Cb. The second shaft 60b may provide a rotation axis of the sub-roller 60. Alternatively, the sub-roller 60 may also be fixed to the second side part 30Cb.

Referring to FIGS. 17 and 18, a bar 52 may be spaced apart from the roller 50 in a radial direction of the roller 50 and may extend in the left-right direction which is the longitudinal direction of the roller 50. The bar 52 may have a solid square lumber shape as a whole. The bar 52 may include metal, such as stainless steel, or plastic material. The bar 52 may be located behind the display panel 11, and may be located closer to the display panel 11 than the roller 50. The bar 52 may be referred to as a pole 52.

A first end of the cover 51 may be fixed to the roller 50, and a second end of the cover 51 may be fixed to the bar 52 (see FIG. 18). The cover 51 may be attached to the bar 52 by an adhesive member, may be heat-sealed, or may be fixed by a screw and the like. A portion of the cover 51 may cover the bar 52, and the portion of the cover 51 may be sandwiched between the bar 52 and a coupler 53 (see FIG. 18). The cover 51 may be wound around or unwound from the roller 50 and may be hung on the sub-roller 60. The cover 51 may include a fabric material. The cover 51 may take on a black color or other colors.

Referring to FIGS. 17 and 19, a first wire reel 40P may be rotatably coupled to an outer lateral surface of the first side part 30Bb and fixed to the shaft 34a of the first gear 34. Accordingly, the first wire reel 40P may rotate together with the first gear 34. The first wire reel 40P may be referred to as a first reel 40P.

Further, the first wire reel 40P may have a generally flat cylindrical shape, and a first groove 40Pg may be formed in an outer circumferential surface of the first wire reel 40P.

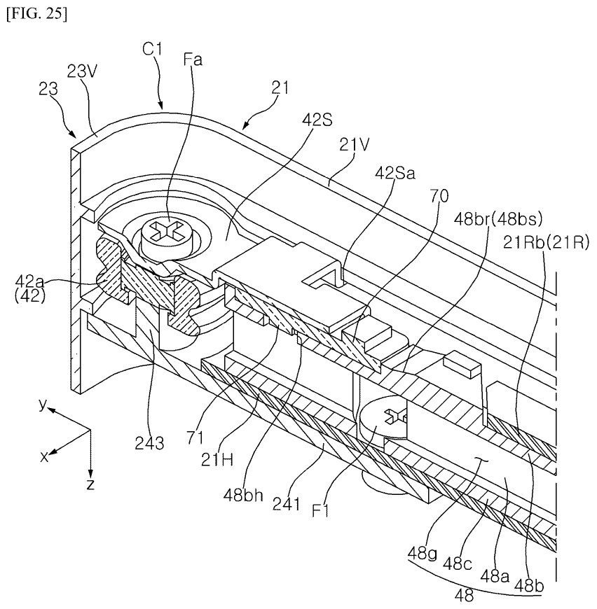

A first upper pulley 42a may be located above the first rail 48 and rotatably coupled or fixed to the side frame 20. A rotation axis of the first upper pulley 42a may be parallel to the front-rear direction. For example, a pin 243 may protrude rearward from a connection portion between the first part 241 and the second part 242 of the first corner brace 24a, and the first upper pulley 42a may be rotatably coupled to the pin 243 (see FIGS. 11 and 12). In this case, the pin 243 may pass through the first and third side frames 21 and 23, and the first upper pulley 42a may be directly coupled to the pin 243 (see FIG. 25). Meanwhile, the first upper pulley 42a and the first lower pulley 41a may be collectively referred to as the first pulley 42a, 41a.

A first end of a first wire 40a may be fixed to the first wire reel 40P. A second end of the first wire 40a may be adjacent to the right end of the bar 52 and fixed to the bar 52. A portion of the first wire 40a may be located in the first groove 40Pg of the first wire reel 40P, and may be wound around or unwound from the first groove 40Pg. Alternatively, instead of the first wire 40a, a first cable, a first rope, a first string, a first chain, a first band, a first strap, or a first belt may be wound around or unwound from the first reel 40P. Alternatively, instead of the first reel 40P, power of the motor 31 may be provided to a first slider that linearly reciprocates in a specific direction (e.g., left-right direction). For example, the first slider may linearly reciprocate along a lead screw fixed to the rotating shaft of the motor 31. In this case, instead of the first wire 40a, a first foldable link may be fixed to the first slider and the right end of the bar 52, and may be unfolded behind the cover 51 to raise the bar 52 or folded to lower the bar 52. The first wire 40a, the first cable, the first rope, the first string, the first chain, the first band, the first strap, the first belt, and the first foldable link may be collectively referred to as a connection member.

The first wire 40a may be sequentially caught on the outer circumference of the first tension pulley 412a, 413a and the outer circumference of the first guide pulley 411a, and may be bent by the first tension pulley 412a, 413a and the first guide pulley 411a. The first wire 40a bent by the first guide pulley 411a may be located on the right of the first rail 48 and may extend in a direction parallel to the first rail 48. The first wire 40a may be caught on the outer circumference of the first upper pulley 42 a and may be bent 180 degrees around the z-axis by the first upper pulley 42a. The first wire 40a bent by the first upper pulley 42a may be located on the left of the first rail 48, may extend in a direction parallel to the first rail 48, and may be fixed to a portion 52a adjacent to the right end of the bar 52.

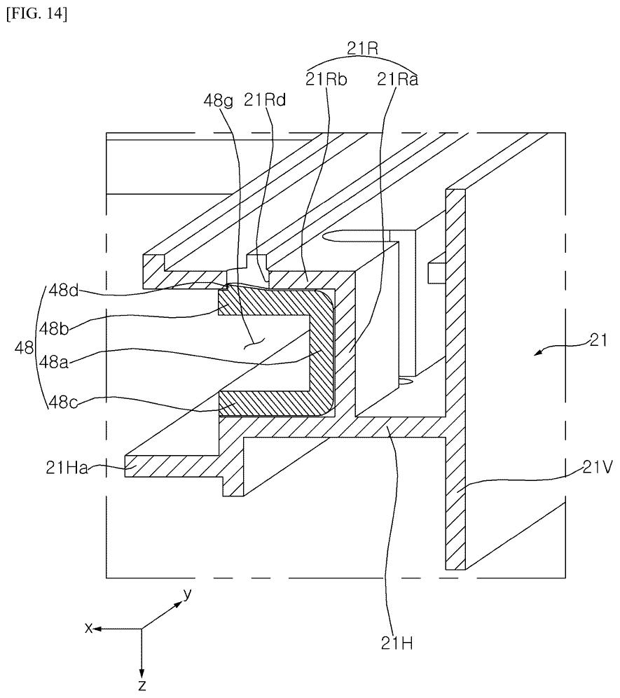

A first protrusion 521 may define the right end of the bar 52 and may be vertically movably inserted into a first guide groove 48g of the first rail 48. The first guide groove 48b may be formed between the first horizontal rib 21Rb of the first rail 48 and the first horizontal portion 21H (see FIG. 14).

Referring to FIGS. 18 and 20, a second wire reel 40Q may be rotatably coupled to an outer lateral surface of the second side part 30Cb and may be fixed to the shaft 37a of the fourth gear 37. Accordingly, the second wire reel 40Q may rotate together with the fourth gear 37. The second wire reel 40Q may be referred to as a second reel 40Q.

Further, the second wire reel 40Q may have a generally flat cylindrical shape, and a second groove 40Qg may be formed in an outer circumferential surface of the second wire reel 40Q.

A second upper pulley 42b may be located above the second rail 49 and rotatably coupled or fixed to the side frame 20. A rotation axis of the second upper pulley 42b may be parallel to the front-rear direction. For example, a pin 243 may protrude rearward from a connection portion between the first part 241 and the second part 242 of the second corner brace 24, and the second upper pulley 42b may be rotatably coupled to the pin 243. In this case, the pin 243 may pass through the second and third side frames 22 and 23, and the second upper pulley 42b may be directly coupled to the pin 243. Meanwhile, the second upper pulley 42b and the second lower pulley 41b may be collectively referred to as the second pulley 42b, 41b.

A first end of a second wire 40b may be fixed to the first wire reel 40Q. A second end of the second wire 40b may be adjacent to the left end of the bar 52 and fixed to the bar 52. A portion of the second wire 40b may be located in the second groove 40Qg of the second wire reel 40Q, and may be wound around or unwound from the second groove 400g. Alternatively, instead of the second wire 40b, a second cable, a second rope, a second string, a second chain, a second band, a second strap, or a second belt may be wound around or unwound from the second reel 40Q. Alternatively, instead of the second reel 40Q, power of the motor 31 may be provided to a second slider that linearly reciprocates in a specific direction (e.g., left-right direction). For example, the second slider may linearly reciprocate along a lead screw fixed to the rotating shaft of the motor 31. In this case, instead of the second wire 40b, a second foldable link may be fixed to the second slider and the left end of the bar 52, and may be unfolded behind the cover 51 to raise the bar 52 or folded to lower the bar 52. The second wire 40b, the second cable, the second rope, the second string, the second chain, the second band, the second strap, the second belt, and the second foldable link may be collectively referred to as a second connection member.

The second wire 40b may be sequentially caught on the outer circumference of the second tension pulley 412b, 413b and the outer circumference of the second guide pulley 411b, and may be bent by the second tension pulley 412b, 413b and the second guide pulley 411b. The second wire 40b bent by the second guide pulley 411b may be located on the left of the second rail 49 and may extend in a direction parallel to the second rail 49. The second wire 40b may be caught on the outer circumference of the second upper pulley 42b and may be bent 180 degrees around the z-axis by the second upper pulley 42 b. The second wire 40 b bent by the second upper pulley 42b may be located on the right of the second rail 49, may extend in a direction parallel to the second rail 49, and may be fixed to a portion 52b adjacent to the left end of the bar 52.

A second protrusion 522 may define the left end of the bar 52 and may be vertically movably inserted into the second guide groove 49g of the second rail 49. The second guide groove 49g may be formed in the right surface of the second rail 49 and may extend vertically.

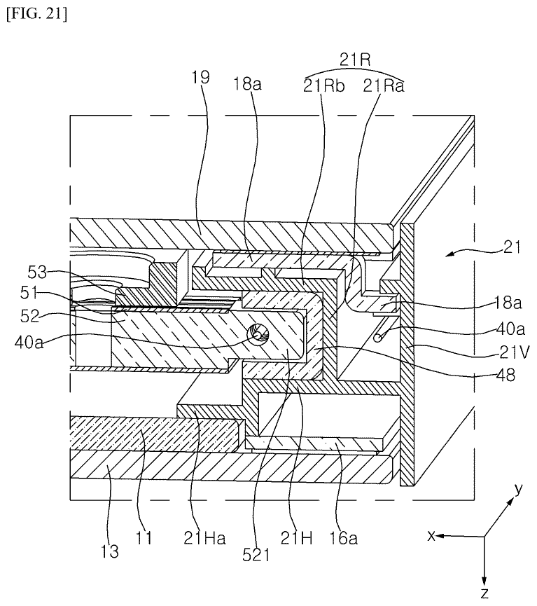

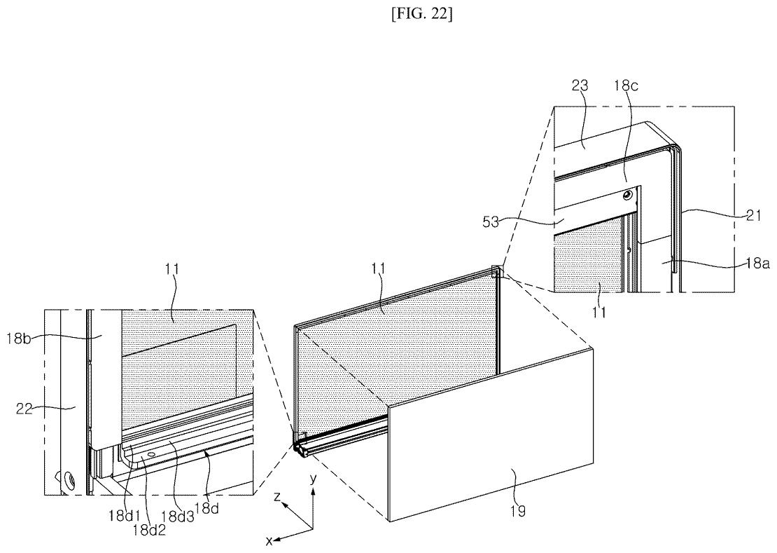

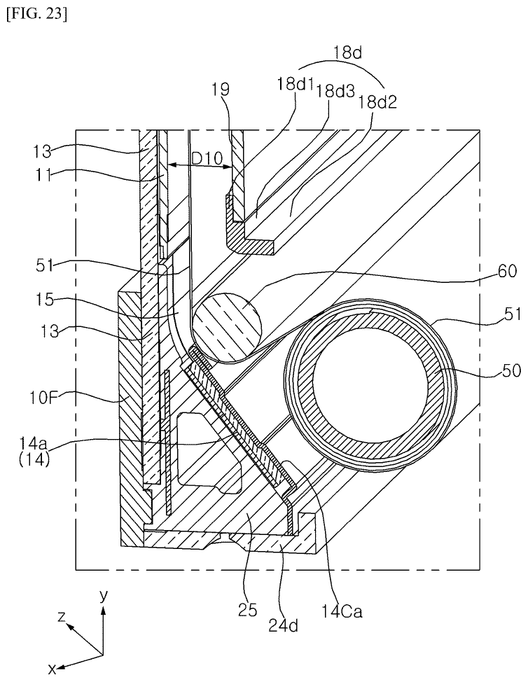

Referring to FIGS. 21 to 24, a cover frame 18a, 18b, 18c, and 18d may extend along the perimeter of the display panel 11 and may be coupled to the side frame 21, 22, and 23. A bottom frame 18d may include a front part 18d1 and a bottom 18d2 that are orthogonal to each other. A back cover 19 may have a size corresponding to the display panel 11 and may be coupled to the rear surface of the cover frame 18a, 18b, 18c, and 18d. The back cover 19 may be made of transparent glass. The bar 52 and the coupler 53 may be raised or lowered in a space (see a gap D10 in FIG. 23) between the display panel 11 and the back cover 19.

The cover 51 may be hung on the auxiliary roller 60, and may be located between the bar 52 and the auxiliary roller 60 and parallel to the display panel 11.

When the first gear 34 rotates in a first rotation direction RD1 in response to operation of the motor 31, the first wire reel 40P and the second wire reel 40Q may rotate in the first rotation direction RD1, and the roller 50 may rotate in a second rotation direction RD2 opposite to the first rotation direction RD1 (see FIGS. 17 to 20). In this case, each of the first wire 40a and the second wire 40b may be wound around the first groove 40Pg and the second groove 40Qg, respectively, and the first wire 40a and the second wire 40b may pull the bar 52 upward. In response to the raising of the bar 52, the cover 51 may be unwound from the roller 50 and may gradually cover the rear of the display panel 11. This motion of the driving assembly 30 may be referred to as an unfolding motion or a light blocking motion.

When the first gear 34 rotates in the second rotation direction RD2 in response to operation of the motor 31, the first wire reel 40P and the second wire reel 40Q may rotate in the second rotation direction RD2, and the roller 50 may rotate in the first rotation direction RD1 opposite to the second rotation direction RD2 (see FIGS. 17 to 20). In this case, each of the first wire 40a and the second wire 40b may be unwound from the first groove 40Pg and the second groove 400g, respectively, and the bar 52 may be lowered downward. In response to the lowering of the bar 52, the cover 51 may be wound around the roller 50 and may gradually open the rear side of the display panel 11. This motion of the driving assembly 30 may be referred to as a rolling motion or opening motion.

In response to the above unfolding or rolling motion, the first protrusion 521 of the bar 52 may slide relative to the inner side of the first rail 48, and the second protrusion 522 of the bar 52 may slide relative to the inner side of the second rail 49. For example, the bar 52 may include a metal material such as stainless steel, and the rails 48 and 49 may include a plastic material having a low friction coefficient such as polyoxymethylene (POM). The bar 52 (e.g., stainless steel) may have a smoother surface than the surface of the side frame 20 (e.g., aluminum) (e.g., surface roughness: bar <side frame). Accordingly, frictional resistance and noise may be minimized which occurs due to movement of the bar 52 on the rails 48 and 49.

Referring to FIGS. 25 to 27, a seating portion 48bs may define a top portion of the first rail 48. A sensor 70 may be mounted on the seating portion 48bs and may be disposed on the inner border of the guide ribs 48br1, 48br2, 48br3, and 48br4 formed on the seating portion 48bs. A sensing unit 71 of the sensor 70 may be provided on one surface of a substrate of the sensor 70 that faces the first rail 48. A sensor hole 48bh may be formed in the rear part 48b of the first rail 48, and the sensing unit 71 may be disposed in the sensor hole 48bh and may face the first guide groove 48g.

For example, the sensor 70 may be a proximity sensor. The sensor 70 may emit an electromagnetic field or electromagnetic waves (e.g., infrared rays) and receive the electromagnetic field or a returning signal. An object, to which the sensor 70 is sensitive, may be the first protrusion 521 of the bar 52 that moves along the first guide groove 48g. The sensor 70 may be an inductive sensor when the first protrusion 521 includes a metal material. The sensor 70 may be a capacitive sensor or a photoelectric sensor when the first protrusion 521 includes a plastic material. In another example, the sensor 70 may be a photo sensor.

Accordingly, the sensor 70 may sense the first protrusion 521 that moves along the first guide groove 48g.

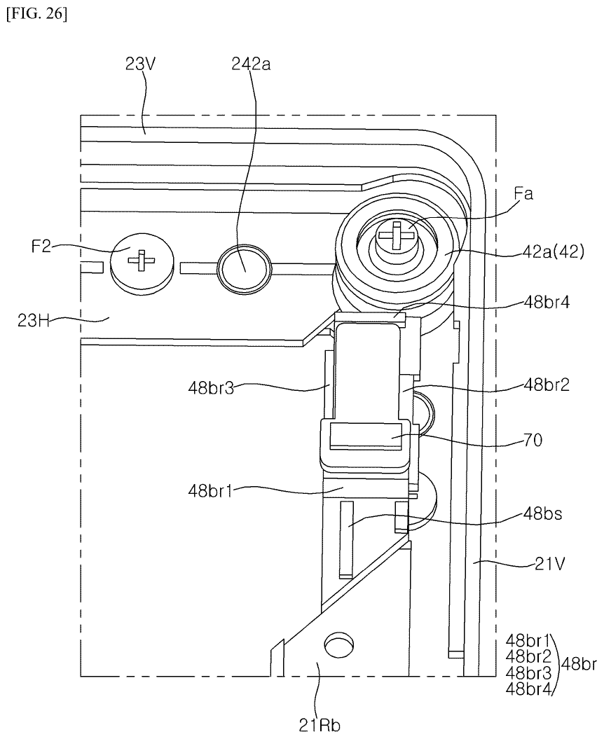

Referring to FIG. 26, for example, if the first protrusion 521 is not detected by the sensor 70, the controller C (see FG. 2) may continuously raise the cover 51 in response to an unfolding motion.

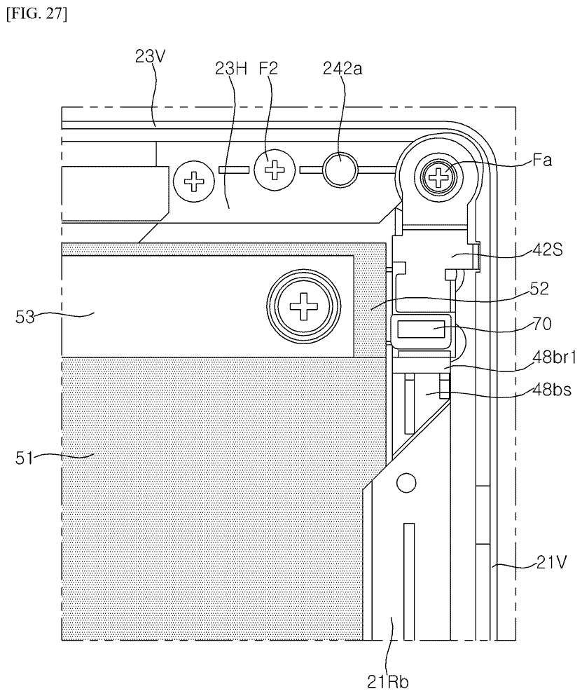

Referring to FIG. 27, for example, if the first protrusion 521 is detected by the sensor 70, the controller C (see FIG. 2) may determine that the cover 51 is raised to the maximum and stop the unfolding motion.

The above sensor 70 may be mounted not only on the top portion of the first rail 48 but also on the top portion of the second rail 49. Alternatively, the sensor 70 may also be mounted on the top portion of the second rail 49 instead of the top portion of the first rail 48.

Meanwhile, a holder 42S may be opposite the first rail 48 with respect to the sensor 70. For example, the holder 42S may be hooked to the first side frame 21 (see a reference numeral 42Sa) and may press the sensor 70 toward the first rail 48. For example, the holder 42S may be screwed to the pin 243 (see a reference numeral Fa) and cover the rear of the first upper pulley 42a.

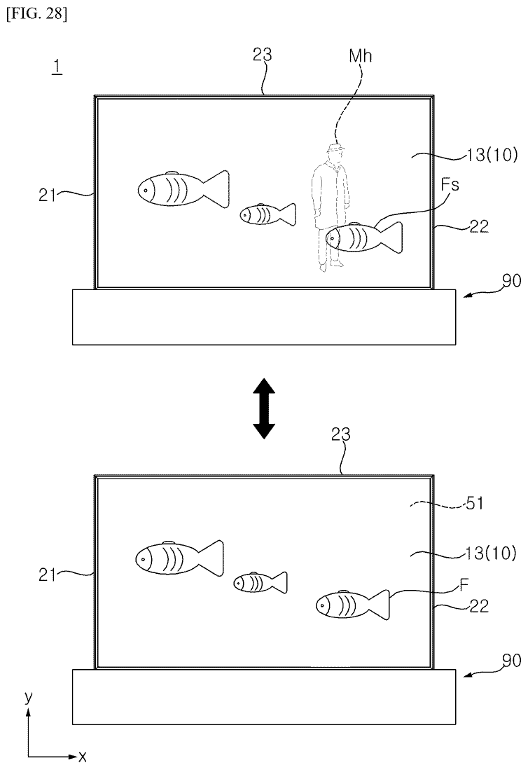

Referring to the upper view of FIG. 28, the cover 51 may not cover the rear of the display 10. For example, the display 10 may not output an image, and a user in front of the display 10 may see behind the display 10 (see a man Mh wearing a hat indicated by the dotted line). In another example, the display 10 may output an image, and a user in front of the display 10 may see the image (see fish Fs indicated by the solid line) and see behind the display 10 (see a man Mh wearing a hat indicated by the dotted line). This mode may be referred to as a light transmitting mode.

Referring to the lower view of FIG. 28, the cover 51 may cover the rear of the display 10. The display 10 may or may not output an image, and a user in front of the display 10 may not see behind the display 10. This mode may be referred to as a light blocking mode.

The visibility of an image output by the display 10 in the light blocking mode may be better than the visibility of an image output by the display 10 in the light transmitting mode (compare the fish Fs indicated by the thin line with the fish F indicated by the thick line in FIG. 28).

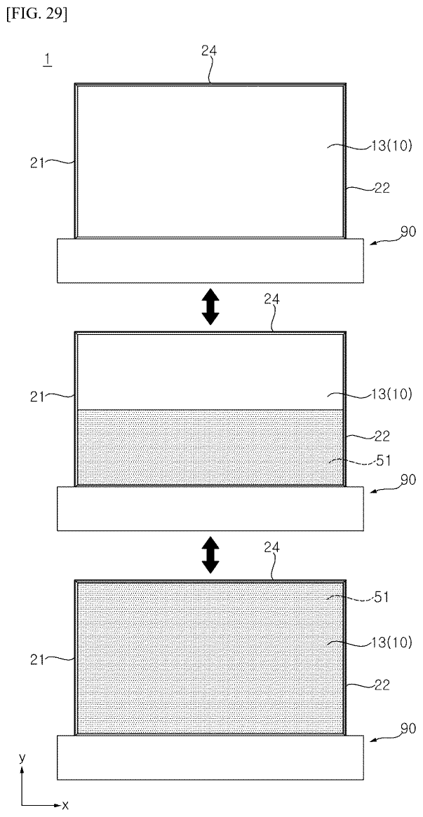

Referring to the upper view of FIG. 29, the cover 51 may not cover the rear of the display 10. This mode may be referred to as a complete light transmitting mode.

Referring to the middle view of FIG. 29, the cover 51 may cover a portion of the rear side of the display 10. This mode may be referred to as a partial light blocking mode or partial light transmitting mode.

Referring to the lower view of FIG. 29, the cover 51 may cover the entire rear side of the display 10. This mode may be referred to as a complete light blocking mode.

The controller C (see FIG. 2) of the display device 1 may switch the display 10 between the light blocking mode and the light transmitting mode by controlling the operation of the driving assembly 30 (see FIG. 2).

Referring to FIGS. 1 to 29, a display device according to an aspect of the present disclosure may include: a display panel displaying an image and having light transparency; a back cover spaced rearward from the display panel and having light transparency; a side frame extending along an edge of the display panel between the display panel and the back cover; and a cover moving between the display panel and the back cover to open or close a rear surface of the display panel, wherein the side frame may include: a first portion covering a lateral side of the display panel; and a second portion which protrudes between the display panel and the back cover from the first portion and to which the display panel and the back cover are coupled.

The first portion and the second portion may be formed as one body.

The side frame may include: a first side frame; and a second side frame intersecting the first side frame and connected to the first side frame, wherein the display device may further include a corner brace coupled to the first side frame and the second side frame between the first side frame and the second side frame.

The corner brace may include: a first part extending along the first side frame and coupled to the second portion of the first side frame; and a second part extending along the second side frame and coupled to the second portion of the second side frame.

The display device may further include: a motor; a connection member fixed to the cover and moving the cover with a force transmitted from the motor; and a pulley on which a portion of the connection member is caught, and changing a direction of force transmitted from the motor to the connection member, wherein the corner brace may include a pin which protrudes from the corner brace and to which the pulley is rotatably coupled.

The second portion may include: a horizontal portion parallel to the display panel and the back cover; a vertical rib protruding from the horizontal portion toward the back cover; and a horizontal rib bent from the vertical rib and facing the horizontal portion.

The display device may further include: a bar to which one side of the cover is fixed, and disposed between the display panel and the back cover; a driving assembly moving the bar; and a rail into which one end of the bar is movably inserted, wherein the rail may be fixed between the horizontal rib and the horizontal portion.

The rail may be elastic, and may have a shape corresponding to an inner border of the horizontal rib, the vertical rib, and the horizontal portion, wherein the rail may include a catching protrusion protruding from a surface of the rail to the horizontal rib or the horizontal portion, wherein the second portion may include a catching hole which is formed in the horizontal rib or the horizontal portion and by which the catching protrusion is removably caught.

The rail may be made of a material different from the bar, wherein the bar may have a lower surface roughness than the side frame.

The rail may include a seating portion disposed outside the horizontal rib, wherein the display device may further include a sensor including a sensor unit mounted on the seating portion and passing through the seating portion to face an inside the rail, wherein the sensor may detect the one end of the bar that moves inside the rail.

The display device may further include a controller electrically connected to the sensor, wherein the controller may adjust a position of the bar based on information acquired by the sensor.

The display device may further include a holder opposite the seating portion with respect to the sensor and coupled to the side frame.

The first portion may include a vertical portion intersecting the horizontal portion and covering the lateral side of the display panel and a lateral side of the back cover.

The side frame may include: a first side frame; a second side frame opposite to the first side frame; and a third side frame connecting one end of the first side frame and one end of the second side frame, wherein the display device may further include: a bar to which a first end of the cover is fixed, the bar having a first end movably coupled to the first side frame and a second end movably coupled to the second side frame; and a driving assembly configured to move the bar.

The display device may further include a roller opposite to the third side frame, extending along one side of the display panel, and to which a second end of the cover is fixed, wherein the cover may close or open the rear surface of the display being unwound from or wound around the roller.

Certain embodiments or other embodiments of the disclosure described above are not mutually exclusive or distinct from each other. Any or all elements of the embodiments of the disclosure described above may be combined or combined with each other in configuration or function.

For example, a configuration “A” described in one embodiment of the disclosure and the drawings and a configuration “B” described in another embodiment of the disclosure and the drawings may be combined with each other. Namely, although the combination between the configurations is not directly described, the combination is possible except in the case where it is described that the combination is impossible.

The foregoing embodiments are merely examples and are not to be considered as limiting the present disclosure. The scope of the present disclosure should be determined by rational interpretation of the appended claims, and all modifications within the equivalents of the disclosure are intended to be included within the scope of the present disclosure.

1. A display device comprising:
a display panel displaying an image and having light transparency;
a back cover spaced rearward from the display panel and having light transparency;
a side frame extending along an edge of the display panel between the display panel and the back cover; and
a cover moving between the display panel and the back cover to open or close
a rear surface of the display panel,
wherein the side frame comprises:
a first portion covering a lateral side of the display panel; and
a second portion which protrudes between the display panel and the back cover from the first portion and to which the display panel and the back cover are coupled.

2. The display device of claim 1, wherein the first portion and the second portion are formed as one body.

3. The display device of claim 1, wherein the side frame comprises:
a first side frame; and
a second side frame intersecting the first side frame and connected to the first side frame,
wherein the display device further comprises a corner brace coupled to the first side frame and the second side frame between the first side frame and the second side frame.

4. The display device of claim 3, wherein the corner brace comprises:
a first part extending along the first side frame and coupled to the second portion of the first side frame; and
a second part extending along the second side frame and coupled to the second portion of the second side frame.

5. The display device of claim 3, further comprising:
a motor;
a connection member fixed to the cover and moving the cover with a force transmitted from the motor; and
a pulley on which a portion of the connection member is caught, and changing
a direction of force transmitted from the motor to the connection member,
wherein the corner brace comprises a pin which protrudes from the corner brace and to which the pulley is rotatably coupled.

6. The display device of claim 1, wherein the second portion comprises:
a horizontal portion parallel to the display panel and the back cover;
a vertical rib protruding from the horizontal portion toward the back cover; and
a horizontal rib bent from the vertical rib and facing the horizontal portion.

7. The display device of claim 6, further comprising:
a bar to which one side of the cover is fixed, and disposed between the display panel and the back cover;
a driving assembly moving the bar; and
a rail into which one end of the bar is movably inserted,
wherein the rail is fixed between the horizontal rib and the horizontal portion.

8. The display device of claim 7, wherein the rail is elastic, and has a shape corresponding to an inner border of the horizontal rib, the vertical rib, and the horizontal portion,
wherein the rail comprises a catching protrusion protruding from a surface of the rail to the horizontal rib or the horizontal portion,
wherein the second portion comprises a catching hole which is formed in the horizontal rib or the horizontal portion and by which the catching protrusion is removably caught.

9. The display device of claim 7, wherein the rail is made of a material different from the bar,
wherein the bar has a lower surface roughness than the side frame.

10. The display device of claim 7, wherein the rail comprises a seating portion disposed outside the horizontal rib,
wherein the display device further comprises a sensor including a sensor unit mounted on the seating portion and passing through the seating portion to face an inside the rail,
wherein the sensor detects the one end of the bar that moves inside the rail.

11. The display device of claim 10, further comprising a controller electrically connected to the sensor,
wherein the controller adjusts a position of the bar based on information acquired by the sensor.

12. The display device of claim 10, further comprising a holder opposite the seating portion with respect to the sensor and coupled to the side frame.

13. The display device of claim 6, wherein the first portion comprises a vertical portion intersecting the horizontal portion and covering the lateral side of the display panel and a lateral side of the back cover.

14. The display device of claim 1, wherein the side frame comprises:
a first side frame;
a second side frame opposite to the first side frame; and
a third side frame connecting one end of the first side frame and one end of the second side frame,
wherein the display device further comprises:
a bar to which one end of the cover is fixed, the bar having one end movably coupled to the first side frame and the other end movably coupled to the second side frame; and
a driving assembly configured to move the bar.

15. The display device of claim 14, further comprising a roller opposite to the third side frame, extending along one side of the display panel, and to which the other end of the cover is fixed,
wherein the cover closes or opens the rear surface of the display while being unwound from or wound around the roller.
